(19) United States
(12) Patent Application Publication
(10) Pub. No.: US 2003/0026135 A1
(43) Pub. Date: Feb. 6, 2003

(54) Data-shifting scheme for utilizing multiple redundant elements

(76) Inventors: J. Michael Hill, Fort Collins, CO (US); Donald R. Weiss, Fort Collins, CO (US); Jonathan E. Lachman, Fort Collins, CO (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 09/919,091

(22) Filed: Jul. 31, 2001

(51) Int. Cl. G11C 7/10

(52) U.S. Cl. 365/189.02; 365/200

(57) ABSTRACT

A data-shifting scheme is implemented where a group of arrays may be selected from a larger set of arrays. The arrays are connected to output-buffers and input-buffers such that data from the selected arrays may be read or written without changing addresses. The arrays are selected by programming the control signals controlling the output-buffers and input-buffers. The control signals may be programmed by several methods, for example, by blowing fuses or storing data in registers. The fuses do not have to be on pitch with the arrays. DRAMs, SRAMs, register arrays, and PLAs are examples of arrays that may be used with this invention. This invention is particularly useful for adding redundancy to an integrated circuit.

### FIELD OF THE INVENTION

This invention relates generally to electronic circuits. More particularly, this invention relates to integrated electronic circuits and redundancy.

### BACKGROUND OF THE INVENTION

In the fabrication of electronic circuits, one technique utilized to increase production yield is to provide redundant circuit elements on the chip to allow for replacement of key circuit elements that prove to be defective. During testing of the chip, the defective portion of the circuit is identified and the redundant circuit element, if one exists, may be activated by opening an associated fuse or similar mechanism. Redundancy is especially suited for repetitive circuits having a large number of repeating elements arranged in some form of an array, such that a redundant circuit element can replace a single defective circuit element in a collection of circuit elements. One such device is a semiconductor memory comprised primarily of memory cells. These memory cells are arranged in rows and columns wherein the redundant circuit element would be either a row or collection of rows of memory cells or a column or collection of columns of memory cells. If, for example, one cell in a given column is defective, the device would be classified as defective. A defective column, or the collection of columns containing the defective column may be replaced by a redundant column or a collection of columns and as a consequence the device would be fully operational. A memory may have, for example, 256 rows and 256 columns. One redundant column would therefore be able to replace one of the 256 columns, thus constituting an efficient use of a redundant circuit.

An integrated circuit (IC) memory generally includes an array of memory cells arranged in rows and columns, each column of cells selected by a column address signal and each row of adjacent cells selected by a row address signal. A redundant column of memory elements may be disposed adjacent a non-redundant array and may be selectable by a predetermined column address with the redundant column memory normally inactive. When a column of memory cells in the nonredundant array is defective, the defective column is deactivated and a circuit is provided for activating the redundant column, such that the redundant column can be addressed by the predetermined column address.

A problem that may be encountered when replacing a column or row in a semiconductor memory is maintaining address integrity; that is, the redundant column must have the same address as the defective column. This is normally implemented by providing a universal decode circuit in association with the redundant column circuitry. Appropriate fuses are included that can be opened to deactivate the defective column, activate the redundant column circuitry and also to program the universal decode circuitry for the appropriate address. The fuses must also be on pitch with the arrays. The area required for fuses and circuitry to access redundant arrays can be fairly large and is an overhead that circuit designers would like to avoid where possible. There is a need in the art for a method for removing or reducing the area required for fuses and circuitry used to access redundant arrays. In addition to the area overhead required to implement redundancy schemes, many redundancy schemes slow the access times when a redundant circuit element is used. IC's may be sorted according to their access times. IC's with shorter access times may be sold at higher prices so IC's that use redundancy schemes that increase access time may not be as valuable as IC's that don't use redundancy. There is a need in the art for a redundancy scheme that does not increase the access time of IC's when redundancy is employed.

Redundancy through data shifting eliminates the need for unique redundant decoders, the programming of a large number of fuses to enable and encode the redundant elements, and deactivate the non-functional circuitry. The small number of fuses required to implement redundancy through data-shifting can easily fit on pitch, or can be remotely located. In addition, redundancy through data-shifting makes it possible to replace an array with a redundant array with no appreciable increase in access time.

### SUMMARY OF THE INVENTION

An embodiment of the invention provides a circuit for deselecting a plurality of arrays from a set of arrays. A set of input-buffers, where each input-buffer has a set of inputs that are input ports to the memory circuit, is connected to the set of arrays such that each output from each input-buffer is connected to a unique array selected from the set of arrays. In addition, a set of output-buffers, where each outputbuffer has a set of inputs that are ports from a set of arrays is connected such that the output from each output-buffer is connected to a unique output port of the memory circuit selected from the set of arrays. The arrays used, for example may be DRAM, SRAM, PLA, or register arrays. The method used in this invention reduces the area needed to implement redundancy as well as reducing the number of fuses needed. The fuses, when using this invention, may be located almost any where on an IC, they don't have to be on pitch as with many other redundancy schemes. In addition, the invention makes it possible to use redundant arrays on an IC with no difference in access time resulting from their use.

Other aspects and advantages of the present invention will become apparent from the following detailed description, taken in conjunction with the accompanying drawing, illustrating by way of example the principles of the invention.

### BRIEF DESCRIPTION OF THE DRAWINGS

FIG. 1 is a schematic drawing of a data-shifting scheme using arrays, including redundant arrays, with output-buffers.

FIG. 2 is a schematic drawing of a data-shifting scheme using arrays, including redundant arrays, with input-buffers.

### DETAILED DESCRIPTION OF THE PREFERRED EMBODIMENT

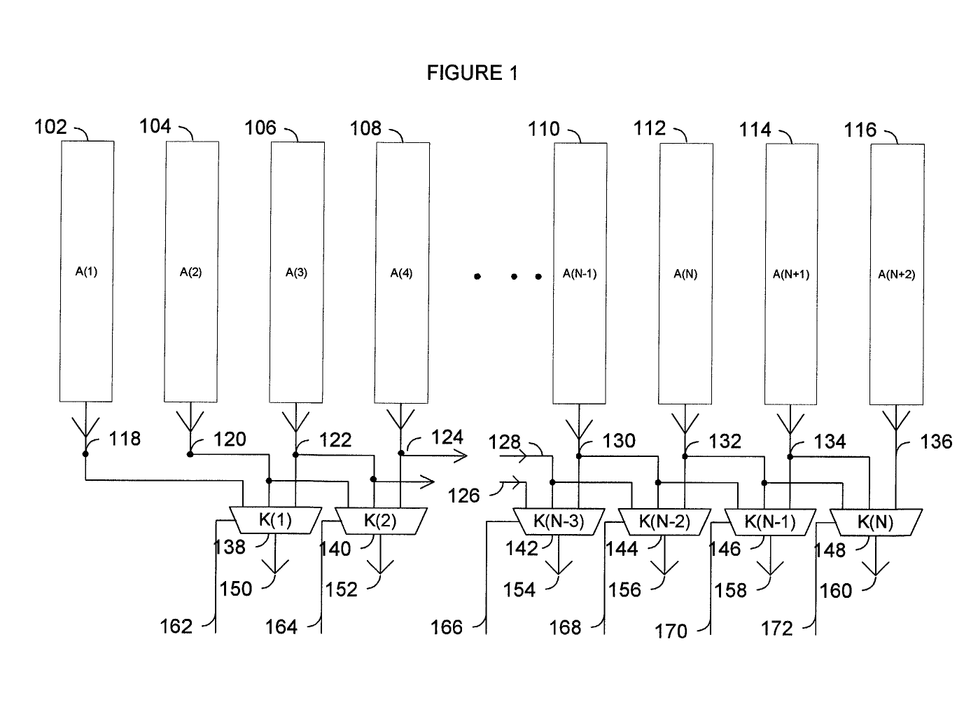

FIG. 1 shows an example of the data-shifting scheme where N arrays are selected from N+2 arrays using output-buffers. In this example each output buffer, K(1)-K(N) has three inputs. The first output-buffer, K(1), 138, has three inputs, 118, 120, and 122 connected to the outputs of the first three arrays, 102, A(1), 104, A(2), and 106 A(3) respectively. Control signal 162, comprising at least two bits of data, 162 [0:1], may be used to select one of the three inputs, 118, 120, and 122 as the output, 150 of the output-buffer, K(1), 138. The second output-buffer, K(2), 140, has three inputs, 120, 122, and 124 connected to the outputs of the three arrays, 104, A(2), 106, A(3), and 108, A(4) respectively. Control signal 164, comprising at least two bits of data, 164 [0:1], may be used to select one of the three inputs, 120, 122, and 124 as the output, 152, of the output-buffer, K(2), 140. This pattern is repeated for the remaining arrays, A(3)-A(N+2) and the remaining output-buffers, K(3)-K(N). The last four of the (N+2) arrays and the last four of the N output-buffers are connected in the following manner. The output-buffer, K(N−3), 142, has three inputs, 126, 128, and 130 connected to the outputs of the three arrays, A(N−3), A(N−2), and 110, A(N−1) respectively. Control signal 166, comprising at least two bits of data, 166 [0:1], may be used to select one of the three inputs, 126, 128, and 130 as the output, 154 of the output-buffer, K(N−3), 142. The output-buffer, K(N−2), 144, has three inputs, 128, 130, and 132 connected to the outputs of the three arrays, A(N−2), A(N−1), 110 and A(N), 112 respectively. Control signal 168, comprising at least two bits of data, 168 [0:1], may be used to select one of the three inputs, 128, 130, and 132 as the output, 156 of the output-buffer, K(N−2), 144. The output-buffer, K(N−1), 146, has three inputs, 130, 132, and 134 connected to the outputs of the three arrays, A(N−1), 110, A(N), 112, and A(N+1), 114 respectively. Control signal 170, comprising at least two bits of data, 170 [0:1], may be used to select one of the three inputs, 130, 132, and 134 as the output, 158 of the output-buffer, K(N−1), 146. The output-buffer, K(N), 148, has three inputs, 132, 134, and 136 connected to the outputs of the three arrays, A(N), 112, A(N+1), 114, and A(N+2), 116 respectively. Control signal 172, comprising at least two bits of data, 172 [0:1], may be used to select one of the three inputs, 132, 134, and 136 as the output, 160 of the output-buffer, K(N), 148. In a first configuration, the control signals may be set to select the third input of each output-buffer, K(1)-K(N). This results in the output of arrays A(3)-A(N+2) being passed through output-buffers, K(1)-K(N) to the outputs of the output-buffers, K(1)-K(N) respectively. The data from A(1), 102 and A(2), 104 is not used.

In a second configuration, arrays A(1), 102 and A(4), 108 are not used. In this configuration, the control signals may be set to select the second input, 120 to outputbuffer K(1), 138 and the second input, 122, to output-buffer K(2), 140. The rest of the output-buffers, K(3)-K(N) use their third input respectively. This results in the outputs of arrays A(2), 104, A(3), 106, and A(N−1)-A(N+2) being passed through output-buffers, K(1)-K(N) to the outputs of the output-buffers, K(1)-K(N) respectively. In this way, the data from A(1), 102 and A(4), 108 are not used. Although the arrays used in this second configuration have changed from the first configuration, the outputs of the output-buffers haven't changed and the addresses to the arrays have not changed. The only changes made were changes in the control signals. The control signals may be programmed by any of several methods, for example, blowing fuses or writing the information to registers.

In a third configuration, arrays A(3), 106, and A(N), 112 are not used. In this configuration, the control signals may be programmed to select the first input, 118, to output-buffer, K(1), 138, the first input, 120, to output-buffer, K(2), 140, the second input, 124, to output-buffer, K(3), the second input, 128, to output-buffer, K(N−3), 142, the second input, 130, to output-buffer, K(N−2), 144, the third input, 134, to output-buffer, K(N−1), 146, and the third input, 136 to output-buffer, K(N), 148. Although the arrays used in this third configuration have changed from the first and second configurations, the outputs of the output-buffers haven't changed and the addresses to the arrays have not changed. The only changes made were changes in the control signals. The three configurations described illustrate how the data-shifting method may be implemented. In these particular configurations, the number of arrays that were deselected was two. This limitation was imposed as a result of the number of inputs to the output-buffers, three. If the number of inputs to each output-buffers is increased, the number of arrays that may be deselected will also increase.

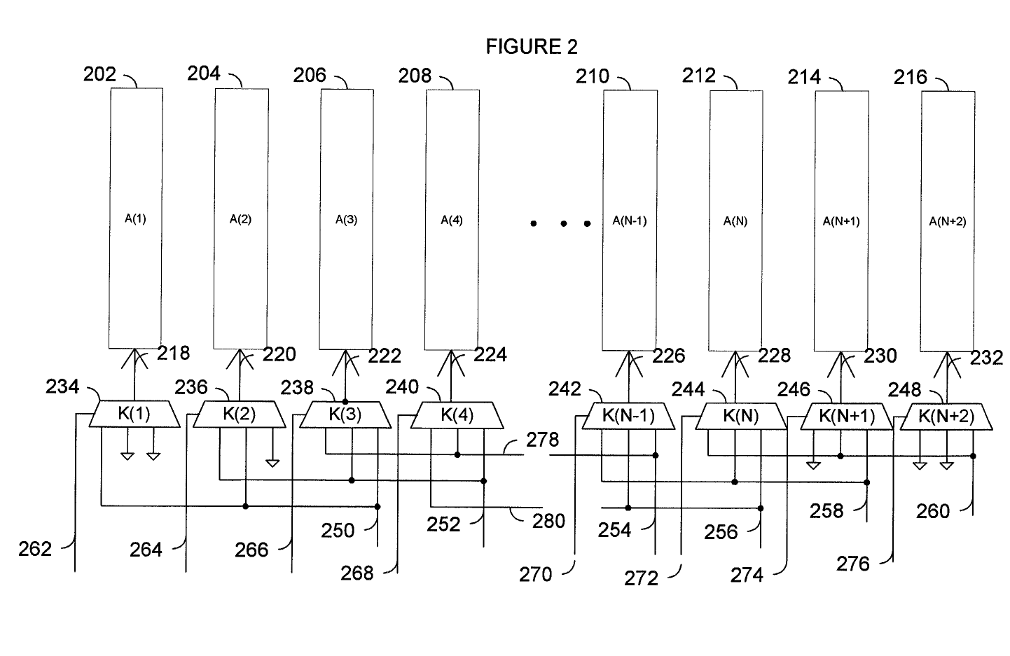

FIG. 2 shows an example of the data-shifting scheme where N arrays are selected from N+2 arrays using N+2 input-buffers. In this example each input-buffer, K(1)-K(N+2) has three inputs. The first input-buffer, K(1), 234, has an output, 218, connected to the input of the array, 202, A(1). Control signal 262, comprising at least two bits of data, 262 [0:1]=VDD, VDD, is used to select input, 250 as the input to the input-buffer, K(1), 234. The second input-buffer, K(2), 236, has an output, 220 connected to the input of array, 204, A(2). Control signal 264, comprising at least two bits of data, 264 [0:1]=VDD, 266[0], may be used to select one of the two inputs, 252 and 250 as the input to input-buffer K(2), 236. The third input-buffer, K(3), 238, has an output, 222 connected to the input of array, 206, A(3). Control signal 266, comprising at least two bits of data, 266 [0:1], may be used to select one of the three inputs, 278, 252, and 250 as the input to input-buffer K(3), 238. The fourth input-buffer, K(4), 240, has an output, 224 connected to the input of array, 208, A(4). Control signal 268, comprising at least two bits of data, 268 [0:1], may be used to select one of the three inputs, 280, 278, and 252 as the input to input-buffer K(4), 240. This pattern is repeated for the remaining arrays, A(5)-A(N+2) and the remaining input-buffers, K(5)-K(N+2). The last four of the (N+2) arrays and the last four of the (N+2) input-buffers are connected in the following manner. The input-buffer, K(N−1), 242, has an output, 226, connected to the input of array, 210, A(N−1). Control signal 270, comprising at least two bits of data, 270 [0:1], may be used to select one of the three inputs, 258, 256, and 254 as the input to the input-buffer, K(N−1), 242. The input-buffer, K(N), 244, has an output, 228, connected to the input of the array, A(N), 212. Control signal 272, comprising at least two bits of data, 272 [0:1], may be used to select one of the three inputs, 260, 258, and 256 as the input of the input-buffer, K(N), 244. The input-buffer, K(N+1), 246, has an output, 230 connected to the input of array, A(N+1), 214. Control signal 274, comprising at least two bits of data, 274 [0:1], may be used to select one of the three inputs, GND, 260, and 258 as the input of the input-buffer, K(N+1), 246. The input-buffer, K(N+2), 248, has an output, 232, connected to the input of array, A(N+2), 216. Control signal 276, comprising at least two bits of data, 276 [0:1]=GND,GND, is used to select input 260 as the input to the input-buffer, K(N+2), 248.

In a fourth configuration, the control signals may be set to select the third input of each input-buffer, K(1)-K(N+2). This results in the data on the third input of input-buffers K(1)-K(N+2) being passed to the inputs of the arrays, K(1)-K(N+2) respectively. The arrays, A(1), 202 and A(2), 204 are ignored.

In a fifth configuration, arrays A(1), 202 and A(4), 208 are not used. In this configuration, the control signals may be set to select the second input, 250 for input-buffer K(2), 236, the second input, 252, for input-buffer K(3), 238, and the second input, 278, for input-buffer K(3), 240. The rest of the input-buffers, K(5)-K(N+2) use their third output respectively. In this way, the arrays A(1), 202 and A(4), 208 are ignored. Although the arrays used in this fifth configuration have changed from the fourth configuration, the inputs of the input-buffers haven't changed and the addresses to the arrays have not changed. The only changes made were changes in the control signals. The control signals may be programmed by any of several methods, for example, blowing fuses or writing the information to registers.

In a sixth configuration, arrays A(3), 206, and A(N), 212 are not used. In this configuration, the control signals may be programmed to select the first input, 250, to input-buffer, K(1), 234, the first input, 252, to input-buffer, K(2), 240, the second input, 278, to input-buffer, K(4), the second output, 256, to input-buffer, K(N−1), 242, the third input, 258, to input-buffer, K(N+1), 246 and the third input, 260, to input-buffer, K(N+2), 248. Although the arrays used in this third configuration have changed from the first and second configurations, the inputs of the input-buffers haven't changed and the addresses to the arrays have not changed. The only changes made were changes in the control signals. The last three configurations described illustrate how the data-shifting method may be implemented. In these particular configurations, the number of arrays that were deselected was two. This limitation was imposed as a result of the number of outputs to the input-buffers, three. If the number of outputs to each input-buffer is increased, the number of arrays that may be deselected will also increase.

Data-shifting may be accomplished for both reading and writing data, by combining input-buffers and output-buffers in one circuit. The same control signals may be used to read or write an individual array. The number of arrays that may be deselected is only limited by the number of inputs to an output-buffer and the number of outputs from an input-buffer.

The foregoing description of the present invention has been presented for purposes of illustration and description. It is not intended to be exhaustive or to limit the invention to the precise form disclosed, and other modifications and variations may be possible in light of the above teachings. The embodiment was chosen and described in order to best explain the principles of the invention and its practical application to thereby enable others skilled in the art to best utilize the invention in various embodiments and various modifications as are suited to the particular use contemplated. It is intended that the appended claims be construed to include other alternative embodiments of the invention except insofar as limited by the prior art.

What is claimed is:

1) A circuit for deselecting a plurality of arrays from a set of arrays comprising:
a set of input-buffers, each member of said set of input-buffers having a set of inputs;
wherein an output from each member of said set of input-buffers is connected to a unique array from said set of arrays;
wherein the number of inputs in said set of inputs is at least three.

2) The circuit as in claim 1 wherein said pluralities of arrays and said set of arrays are DRAM arrays.

3) The circuit as in claim 1 wherein said pluralities of arrays and said set of arrays are SRAM arrays.

4) The circuit as in claim 1 wherein said pluralities of arrays and said set of arrays are register arrays.

5) The circuit as in claim 1 wherein said pluralities of arrays and said set of arrays are PLA arrays.

6) A circuit for deselecting a plurality of arrays from a set of arrays comprising:
a set of output-buffers, each member of said set of output-buffers having a set of inputs;
wherein said set of inputs to each member of said set of output-buffers is connected to a unique group of said set of arrays;
wherein the number of inputs in said set of inputs is at least three.

7) The circuit as in claim 6 wherein said pluralities of arrays and said set of arrays are DRAM arrays.

8) The circuit as in claim 6 wherein said pluralities of arrays and said set of arrays are SRAM arrays.

9) The circuit as in claim 6 wherein said pluralities of arrays and said set of arrays are register arrays.

10) The circuit as in claim 6 wherein said pluralities of arrays and said set of arrays are PLA arrays.

11) A circuit for deselecting two arrays from N+2 arrays comprising:
N+2 input-buffers, each member of said N input-buffers having three inputs, K, K+1, K+2;
wherein an output from each member of said N +2 input-buffers is connected to a unique array from said set of N+2 arrays.

12) The circuit as in claim 11 wherein said arrays are DRAM arrays.

13) The circuit as in claim 11 wherein said arrays are SRAM arrays.

14) The circuit as in claim 11 wherein said arrays are register arrays.

15) The circuit as in claim 11 wherein said arrays are PLA arrays.

16) A circuit for deselecting two arrays from N+2 arrays comprising:
N output-buffers, each member of said N output-buffers having three inputs, K, K+1, K+2;
wherein each of said three inputs, K, K+1, K+2 from each member of said N output-buffers are connected to outputs of three consecutive arrays, A, A+1, A+2 respectively such that no output-buffer is connected to the same three outputs of three arrays as any other output-buffer.

17) The circuit as in claim 16 wherein said arrays are DRAM arrays.

18) The circuit as in claim 16 wherein said arrays are SRAM arrays.

19) The circuit as in claim 16 wherein said arrays are register arrays.

20) The circuit as in claim 16 wherein said arrays are PLA arrays

21) A method for deselecting a plurality of arrays from a set of arrays comprising:
demultiplexing a set of inputs to each input-buffer of a set of input-buffers;
wherein an output from each member of said set of input-buffers is connected to a unique array from said set of arrays;
wherein the number of inputs to said set of inputs is at least three.

22) The circuit as in claim 21 wherein said pluralities of arrays and said set of arrays are DRAM arrays.

23) The circuit as in claim 21 wherein said pluralities of arrays and said set of arrays are SRAM arrays.

24) The circuit as in claim 21 wherein said pluralities of arrays and said set of arrays are register arrays.

25) The circuit as in claim 21 wherein said pluralities of arrays and said set of arrays are PLA arrays.

26) A method for deselecting a plurality of arrays from a set of arrays comprising:
multiplexing a set of inputs to each output-buffer of a set of output-buffers;
wherein said set of inputs to each member of said set of output-buffers is connected to a unique group of said set of arrays;
wherein the number of inputs in said set of inputs is at least three.

27) The circuit as in claim 26 wherein said pluralities of arrays and said set of arrays are DRAM arrays.

28) The circuit as in claim 26 wherein said pluralities of arrays and said set of arrays are SRAM arrays.

29) The circuit as in claim 26 wherein said pluralities of arrays and said set of arrays are register arrays.

30) The circuit as in claim 26 wherein said pluralities of arrays and said set of arrays are PLA arrays.

31) A method for deselecting two arrays from N+2 arrays comprising:
demultiplexing three inputs, K, K+1, K+2, from each member of the set of N+2 input-buffers;
wherein an output from each member of said N+2 input-buffers is connected to an input of each member of said N+2 arrays such that no input-buffer is connected to the same array as any other input-buffer.

32) The circuit as in claim 31 wherein said arrays are DRAM arrays.

33) The circuit as in claim 31 wherein said arrays are SRAM arrays.

34) The circuit as in claim 31 wherein said arrays are register arrays.

35) The circuit as in claim 31 wherein said arrays are PLA arrays.

36) A method for deselecting two arrays from N+2 arrays comprising:
multiplexing three inputs, K ,K+1, K+2, for each member of the set of N output-buffers;
wherein each of said three inputs, K−1, K, K+1 to each member of said N output-buffers are connected to outputs of three consecutive arrays, A, A+1, A+2 respectively such that no output-buffer is connected to the same three inputs of three arrays as any other output-buffer.

37)The method as in claim 36 wherein said arrays are DRAM arrays.

38) The method as in claim 36 wherein said arrays are SRAM arrays.

39) The method as in claim 36wherein said arrays are register arrays.

40) The method as in claim 36 wherein said arrays are programmable arrays.
